(19) United States
(12) Patent Application Publication
(10) Pub. No.: US 2026/0104447 A1
(43) Pub. Date: Apr. 16, 2026

(54) ADAPTIVE SEMICONDUCTOR TESTING METHOD AND SYSTEM FOR MULTIPLE ENVIRONMENTAL CONDITIONS

(71) Applicant: MEDIATEK INC., Hsinchu City (TW)

(72) Inventors: Cheng-Tien Wan, Hsinchu City (TW); Wei-Lien Chen, Hsinchu City (TW); Hung-Yu Chiou, Hsinchu City (TW); Yu-Lin Yang, Hsinchu City (TW); Chin-Wei Lin, Hsinchu City (TW); Chia-Chun Sun, Hsinchu City (TW); Yun-San Huang, Hsinchu City (TW); Po-Chao Tsao, Hsinchu City (TW); Ming-Cheng Lee, Hsinchu City (TW); Tung-Hsing Lee, Hsinchu City (TW)

(73) Assignee: MEDIATEK INC., Hsinchu City (TW)

(21) Appl. No.: 19/352,407

(22) Filed: Oct. 7, 2025

Related U.S. Application Data
(60) Provisional application No. 63/706,085, filed on Oct. 11, 2024.

(51) Int. Cl. G01R 31/26

(52) U.S. Cl. CPC G01R 31/2642

(57) ABSTRACT

A testing method for use in semiconductor device testing, includes: performing at least one test item from a set of test items on a semiconductor device under a first environmental condition; generating, via a machine learning model and based on a test result of the at least one test item, a qualification result predictive of at least one test result for one or more test items from the set of test items when performed on the semiconductor device under a second environmental condition; and determining, based on the qualification result, whether to perform the one or more test items from the set of test items on the semiconductor device under the second environmental condition.

### CROSS REFERENCE TO RELATED APPLICATIONS

This application claims the benefit of U.S. Provisional Application No. 63/706,085, filed on October 11th, 2024. The content of the application is incorporated herein by reference.

### BACKGROUND

The present invention relates to semiconductor device testing, and more particularly, to an adaptive testing method and system for optimizing the test process across multiple environmental conditions based on predictive analysis of test results.

In semiconductor manufacturing, chip probing testing is an essential process to ensure the reliability and functionality of semiconductor devices. Conventionally, to validate operational stability of a semiconductor device across different environmental conditions, comprehensive testing is performed at multiple environmental conditions, typically including normal environmental conditions and extreme environmental conditions. For example, a semiconductor device may be tested under room temperature, high temperature, and low temperature conditions. This conventional testing methodology requires executing a complete set of test items at each environmental condition.

The conventional testing methodology presents significant challenges in terms of testing efficiency and cost-effectiveness. For example, when a semiconductor device undergoes testing at different temperatures, many test items are repeatedly executed despite their relative insensitivity to temperature variations. Such approach leads to unnecessary testing overhead, particularly when certain test items demonstrate consistent results across different temperature conditions, or when specific semiconductor devices exhibit stable performance characteristics.

In view of above, there is a need in the semiconductor testing field for an adaptive testing methodology that can optimize the testing process by identifying and eliminating redundant testing operations while maintaining the reliability and quality of the semiconductor devices.

### SUMMARY

With this in mind, it is object of the present invention provide to an adaptive testing method and system that optimizes semiconductor device testing across multiple environmental conditions while maintaining quality assurance. The present invention employs a machine learning model to analyze test results obtained under initial environmental conditions and generates qualification results that predict the necessity of repeated testing under other environmental conditions. This intelligent prediction mechanism significantly reduces testing redundancy while ensuring semiconductor device reliability across various environmental conditions.

According to one embodiment, a testing method for use in semiconductor device testing is provided. The testing method comprises: performing at least one test item from a set of test items on a semiconductor device under a first environmental condition; generating, via a machine learning model and based on a test result of the at least one test item, a qualification result predictive of at least one test result for one or more test items from the set of test items when performed on the semiconductor device under a second environmental condition; and determining, based on the qualification result, whether to perform the one or more test items from the set of test items on the semiconductor device under the second environmental condition.

According to one embodiment, a testing system for use in semiconductor device testing is provided. The testing system comprises a testing equipment and a testing control module. The testing equipment is configured to perform at least one test item from a set of test items on a semiconductor device under a first environmental condition. The testing control module is configured to: generate, via a machine learning model and based on a test result of the at least one test item, a qualification result predictive of at least one test result for one or more test items from the set of test items when performed on the semiconductor device under a second environmental condition; and determine, based on the qualification result, whether to control the testing equipment to perform the one or more test items from the set of test items on the semiconductor device under the second environmental condition.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a testing system for use in semiconductor device testing according to one embodiment of the present invention.

FIG. 2 illustrates a flow chart of a testing method according to one embodiment of the present invention.

FIG. 3 illustrates an implementation of a testing control module according to one embodiment of the present invention.

FIG. 4 illustrates testing methodology implemented by a testing control module for controlling a testing equipment according to one embodiment of the present invention.

FIG. 5 illustrates testing methodology implemented by a testing control module for controlling a testing equipment according to another embodiment of the present invention.

FIG. 6 illustrates how to determine predetermined thresholds for evaluating holistic qualification scores and item-specific qualification scores.

FIG. 7 illustrates a partial structure of a machine learning model implemented in one embodiment of the present invention.

### DETAILED DESCRIPTION

In the following description, numerous specific details are set forth in order to provide a thorough understanding of the present embodiments. It will be apparent, however, to one having ordinary skill in the art that the specific detail need not be employed to practice the present embodiments. In other instances, well-known materials or methods have not been described in detail in order to avoid obscuring the present embodiments.

Reference throughout this specification to “one embodiment” or “an embodiment” means that a particular feature, structure or characteristic described in connection with the embodiment or example is included in at least one embodiment of the present embodiments. Thus, appearances of the phrases “in one embodiment” or “in an embodiment” in various places throughout this specification are not necessarily all referring to the same embodiment. Furthermore, the particular features, structures or characteristics may be combined in any suitable combinations and/or sub-combinations in one or more embodiments.

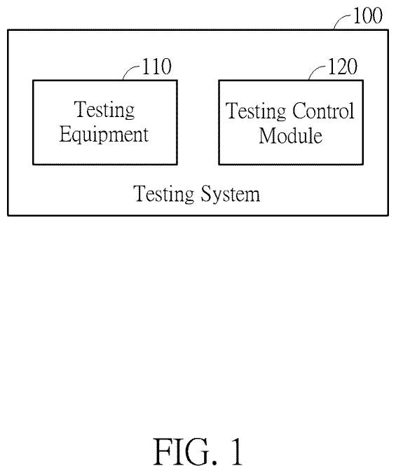

Please refer to FIG. 1, which illustrates a schematic diagram of a testing system for use in semiconductor device testing according to one embodiment of the present invention. As illustrated, a testing system 100 comprises a testing equipment 110 and a testing control module 120. The testing equipment 110 is configured to perform test items on semiconductor devices. As used herein, the term “test item” refers to a specific testing procedure designed to evaluate a particular characteristic, function, or parameter of the semiconductor device under test. As used herein, the term “semiconductor device” refers to a semiconductor die configured to be tested during various stages of manufacture, wherein the stages comprise: 1) a formation stage wherein the semiconductor die is present on a wafer before separation; 2) a post-separation stage wherein the semiconductor die is separated from the wafer and remains unpackaged; and 3) a packaging stage wherein the semiconductor die is incorporated into a packaged semiconductor device.

In some embodiments, the test items may comprise two categories: 1) categorical test items and 2) parametric test items. Specifically, each categorical test item is configurable to generate a test result selected from a finite set of predefined outcomes, wherein each predefined outcome indicates whether specific parameters or functions of the semiconductor device meet predetermined criteria through one or more iterations of testing. For instance, such categorical test items may include logic testing items, such as automatic test pattern generation (ATPG) for detecting manufacturing defects, or memory testing items, such as a memory built-in self-test (MBIST), both of which typically yield a pass or fail result. The predefined outcomes may further specify results obtained through one or more iterations of testing, such as meeting or failing to meet the predetermined criteria in a single iteration (e.g., pass or fail), meeting the predetermined criteria in all iterations (e.g., all pass), meeting the predetermined criteria in some iterations while failing to meet the predetermined criteria in other iterations (e.g., fail first and then pass), or failing to meet the predetermined criteria in all iterations (e.g., all fail). As used herein, an “iteration” of testing refers to a single execution of a specific test item under the same condition. Therefore, performing multiple iterations allows for the verification of result stability or the identification of specific outcome patterns. In addition, each parametric test item is configurable to generate a test result comprising a measurement value that quantifies a specific electrical, physical, or operational characteristic of the semiconductor device. In some embodiments, examples of parametric test items include the measurement of leakage current when a transistor is in an off-state, or the determination of a threshold voltage (Vth) of transistors, both of which provide a continuous numerical value crucial for assessing device performance and reliability.

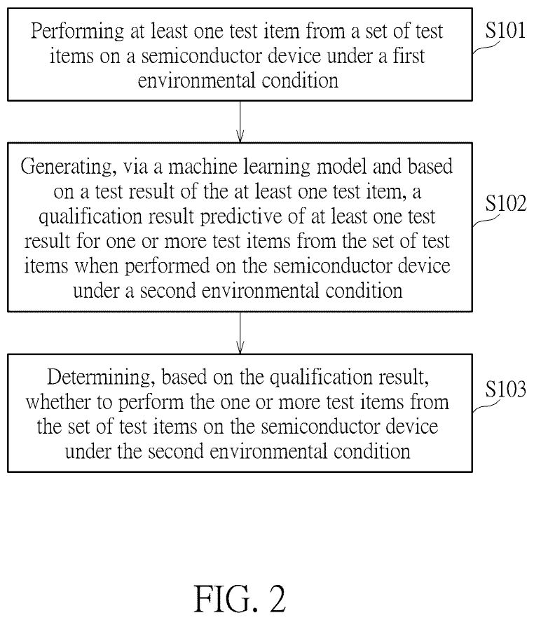

In order to optimize the efficiency of the testing process, the testing control module 120 is configured to control the testing equipment 110 based on a testing method provided by the present invention. Please refer to FIG. 2, which illustrates a flow chart of a testing method according to one embodiment. At step S101, the testing equipment 100 is configured to perform at least one test item from a set of test items on a semiconductor device (at least one semiconductor device) under a first environmental condition, wherein the set of test items may comprise at least one of the categorical test item and the parametric test item.

At step S102, the testing control module 120 is configured to generate, via a machine learning model and based on a test result of the at least one test item, a qualification result predictive of at least one test result for one or more test items from the set of test items when performed on the semiconductor device (the at least one semiconductor device) under a second environmental condition. As used herein, the “qualification result” is a predictive output generated by the machine learning model, rather than a direct measurement from the semiconductor device (the at least one semiconductor device). It is derived from initial test results of the categorical and parametric test items, which serve as input features for the machine learning model. The qualification result may be embodied as one or more numerical scores or data indicators. For example, as will be detailed in subsequent embodiments, it can be a single “holistic qualification score” evaluating overall reliability of the semiconductor device (the at least one semiconductor device), or a set of “item-specific qualification scores” each corresponding to a specific future test item. Ultimately, this result serves as a basis for determining the necessity of subsequent testing under the second environmental condition.

According to various embodiments of the present invention, an environmental condition comprises one or more environmental parameters selected from: temperature, voltage, humidity, pressure, or other environmental parameters that may affect the performance or reliability of the semiconductor device (the at least one semiconductor device). In addition, the first environmental condition differs from the second environmental condition in at least one of these environmental parameters. For example, the first environmental condition may be room temperature (i.e., a nominal operating environment) while the second environmental condition may be either an elevated temperature of 80 degrees C. or a reduced temperature of −40 degrees C. (i.e., extreme operating environments).

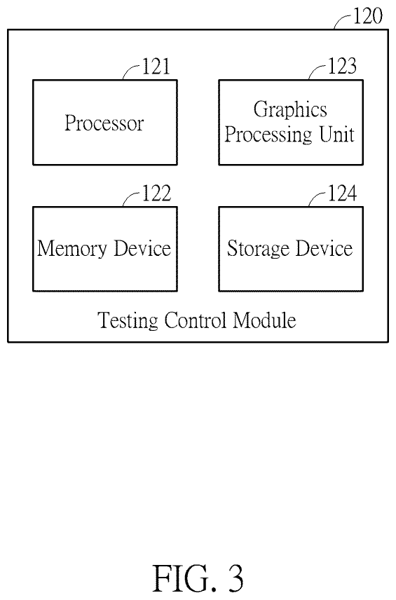

At step S103, the testing control module 120 is configured to determine, based on the qualification result, whether to control the testing equipment 110 to perform the one or more test items from the set of test items on the semiconductor device (the at least one semiconductor device) under the second environmental condition. Please refer to FIGS. 3-5 for further understanding on the testing control module 120.

FIG. 3 illustrates an implementation of the testing control module 120 according to one embodiment of the present invention. As illustrated, the testing control module 120 typically comprises at least one processor 121, one or more memory devices 122, a graphics processing unit (GPU) 123 and a storage device 124. The processor 121 could be a high-performance multi-core central processing unit (CPU), capable of handling complex computations required for model training and inference. Alternatively, for specialized machine learning tasks, the testing control module 120 might employ application-specific integrated circuits (ASICs), or field-programmable gate arrays (FPGAs) designed specifically for model operations. The memory device 122 stores model parameters and intermediate computational results, which may implement a hierarchical memory architecture comprising: a static random access memory (SRAM) configured to facilitate ultra-high-speed data transfers; a high bandwidth memory (HBM) configured to facilitate large-scale and high-speed data transfers; and a dynamic random access memory (DRAM) configured to facilitate large-scale data transfers. In some embodiments, the testing control module 120 could leverage GPU 123, which excels at parallel processing tasks common in machine learning workloads. The storage device 124 may comprise non-volatile memory express (NVMe) solid-state drives for rapid storage and retrieval of model data. The testing control module 120, through the integration of these hardware components, is configured to execute machine learning operations and control the testing equipment 110 to perform adaptive testing of semiconductor devices based on generated qualification results.

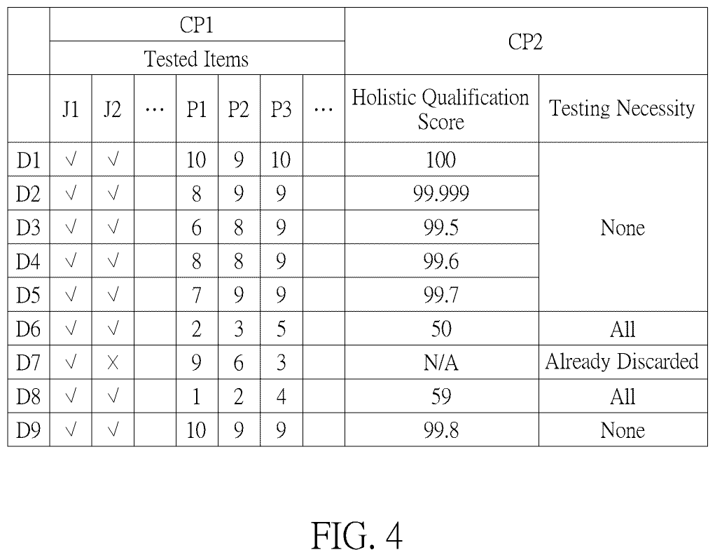

In one embodiment of the present invention, the testing control module 120 is configured to control the testing equipment 110 based on testing methodology illustrated by FIG. 4. As illustrated by FIG. 4, the testing methodology comprises two sequential phases: testing under a first environmental condition CP1 and testing under a second environmental condition CP2. In addition, under the first environmental condition CP1, at least categorical test items J1 and J2, and at least parametric test items P1, P2, and P3 are performed by the testing equipment 110 on semiconductor devices D1-D9. For example, the plurality of semiconductor devices includes semiconductor devices D1 to D9, and the at least one semiconductor device refers to one or more of semiconductor devices D1 to D9.

During testing under the first environmental condition CP1, each of semiconductor devices D1-D9 obtains test results comprising outcomes (e.g., “V” represents pass or “X” represents fail) for the categorical test items J1-J2 and measurement values for the parametric test items P1-P3. Please note that the values shown in FIG. 4 for parametric test items P1-P3 may not represent raw measurement values. Instead, these values may represent either quantified results derived from the raw measurement values of parametric test items P1-P3, or scores calculated based on the raw measurement values of parametric test items P1-P3.

Based on the test results (i.e., results on each categorical test item and on each parametric test) generated in testing under the first environmental condition CP1, the testing control module 120 generates a qualification result comprising a holistic qualification score by inputting the generated test results to the machine learning model. In this embodiment, the holistic qualification score for a semiconductor device evaluates the semiconductor device's overall reliability under the second environmental condition CP2. The holistic qualification score serves as a reliability indicator to determine whether the semiconductor device requires comprehensive testing under the second environmental condition CP2.

For instance, the machine learning model may take the test results from the initial set of test items, including outcomes from categorical test items (e.g., J1 and J2) and measurement values from parametric test items (e.g., P1, P2, and P3), as a multi-dimensional input vector to derive the aggregated holistic qualification score. When the holistic qualification score exceeds a predetermined threshold (e.g., 60), it indicates high confidence in the semiconductor device's performance stability across different environmental conditions, suggesting that testing under the second environmental condition CP2 can be safely skipped. On the other hand, when the holistic qualification score is lower than the predetermined threshold of 60, it indicates low confidence, suggesting that comprehensive testing under the second environmental condition CP2 should be performed on the semiconductor device.

According to the determination generated based on the holistic qualification scores and the predetermined threshold, the testing control module 120 is configured to control the testing equipment 110 to either repeat all the test items in the set of the test items (e.g., J1-J2 and P1-P3) or skip execution of all the test items in the set of the test items on the corresponding semiconductor device under the second environmental condition CP2.

Besides, with respect to the semiconductor device D7, since its test result for a categorical test item J2 indicates a failure under the first environmental condition CP1, the testing control module 120 is configured to discard the semiconductor device D7 and accordingly skip generation of any qualification result of the semiconductor device D7 for subsequent testing under the second environmental condition CP2.

The adaptive testing methodology illustrated by FIG. 4 demonstrates significant efficiency improvement by eliminating unnecessary testing while maintaining quality assurance standards.

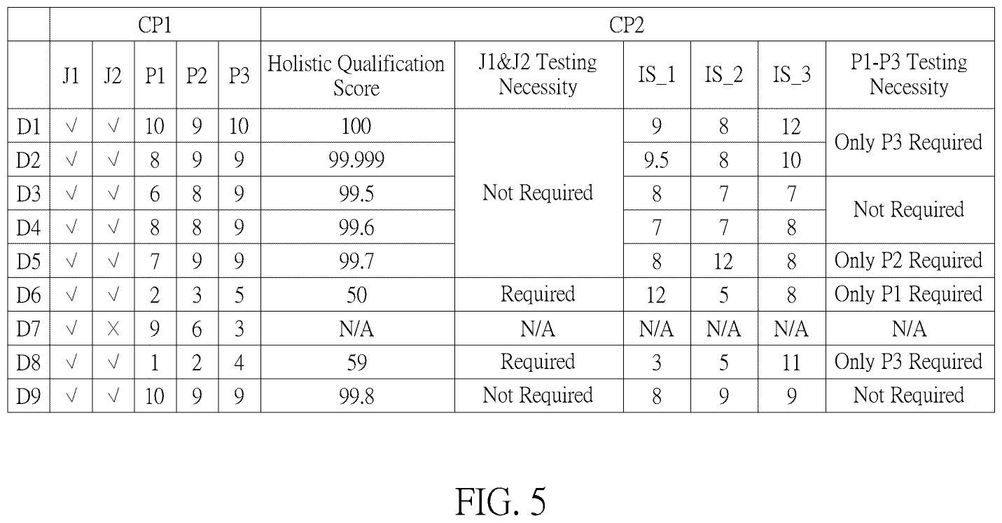

In another embodiment of the present invention, a more granular approach is provided to testing optimization by generating both holistic and item-specific qualification scores in the qualification result. This testing methodology enables selective execution of individual test items under the second environmental condition CP2. Please refer to FIG. 5 for further understanding.

Similar to the embodiment of FIG. 4, the testing methodology comprises testing under the first environmental condition CP1 and testing under the second environmental condition CP2. In addition, under the first environmental condition CP1, at least categorical test items J1 and J2, and at least parametric test items P1, P2, and P3 are performed by the testing equipment 110 on semiconductor devices D1-D9 (a plurality of semiconductor devices). For example, the plurality of semiconductor devices includes semiconductor devices D1 to D9, and the at least one semiconductor device refers to (or comprises) one or more of semiconductor devices D1 to D9.

Based on test results of the test items performed under the first environmental condition CP1, the machine learning model is configured to generate, for each of semiconductor devices D1-D9, item-specific qualification scores IS_1-IS_3 respectively corresponding to necessity of the parametric test items P1-P3 under the second environmental condition CP2 and one holistic qualification score corresponding to necessity of the categorical test items J1-J2 under the second environmental condition CP2.

First, based on the holistic qualification scores of the semiconductor devices D1-D9 and a predetermined threshold of 60,the testing control module 120 is configured to determine whether the categorical test items J1 and J2 need to be repeated on each of the semiconductor devices D1-D9 under the second environmental condition CP2. For example, since the semiconductor devices D1, D2, D3, D4, D5 and D9 have holistic qualification scores above 60, the testing control module 120 is configured to control the testing equipment 110 to skip execution of the categorical test items J1 and J2 on the semiconductor devices D1, D2, D3, D4, D5 and D9 under the second environmental condition CP2. On the other hand, as the semiconductor devices D6 and D8 have holistic qualification scores below 60, the testing control module 120 is configured to control the testing equipment 110 to repeat the categorical test items J1 and J2 on the semiconductor devices D6 and D8 under the second environmental condition CP2.

Second, based on the item-specific qualification scores corresponding to each of the parametric tests P1-P3 and a predetermined threshold of 10 (for illustrative purposes), the testing control module 120 is configured to determine whether each of the parametric tests P1-P3 need to be repeated on each of the semiconductor devices D1-D9 under the second environmental condition CP2. For example, as the item-specific qualification score IS_1 for the semiconductor device D6 exceeds the predetermined threshold of 10 (wherein higher scores indicating lower confidence in the semiconductor device's performance stability and lower scores indicating higher confidence in the semiconductor device's performance), the testing control module 120 is configured to control the testing equipment 110 to repeat the parametric test item P1 on the semiconductor device D6 under the second environmental condition CP2. For example, as the item-specific qualification score IS_2 for the semiconductor device D5 exceeds the predetermined threshold of 10, the testing control module 120 is configured to control the testing equipment 110 to repeat the parametric test item P2 on the semiconductor device D5 under the second environmental condition CP2. For example, as the item-specific qualification score IS_3 for the semiconductor devices D1, D2 and D8 exceeds the predetermined threshold of 10, the testing control module 120 is configured to control the testing equipment 110 to repeat the parametric test item P3 on the semiconductor devices D1, D2 and D8 under the second environmental condition CP2.

In addition, this testing methodology also maintains strict quality control by immediately discontinuing the testing process for the semiconductor device D7 that fails categorical test item J2 under the first environmental condition CP1. The semiconductor device D7 is marked as “N/A” for all subsequent predictions and tests, ensuring that defective devices are properly identified and segregated early during the testing process.

While the above embodiments describe predicting the necessity of testing under the second environmental condition CP2 based solely on test results obtained under the first environmental condition CP1, the present invention is not limited to such implementations. In alternative embodiments, the prediction of testing necessity under a third environmental condition CP3 may be determined based on test results obtained under both the first environmental condition CP1 and the second environmental condition CP2. Furthermore, it is also possible to simultaneously predict the necessity of testing under both the second environmental condition CP2 and the third environmental condition CP3 based on test results obtained under the first environmental condition CP1.

Additionally, although in the above embodiments qualification results are generated based on specific categorical test items J1-J2 and parametric test items P1-P3 performed under the first environmental condition CP1, the number and types of test items are not limiting the scope of the present invention. In various embodiments, qualification results may be generated based on a different number of categorical and/or parametric test items performed under the first environmental condition CP1. Moreover, the qualification results may be determined based on test results from either categorical test items alone or parametric test items alone, with one or more test items of the selected type.

In view of above, the testing methodology of FIG. 5 demonstrates a balance between testing thoroughness and efficiency by: evaluating the necessity of categorical tests based on holistic qualification scores, independently assessing the necessity of each parametric test based on item-specific qualification scores.

As demonstrated in the above embodiments, while the holistic qualification scores and item-specific qualification scores provide predictive indicators, the selection of predetermined thresholds plays a crucial role in determining whether test items need to be repeated under the second environmental condition CP2. The threshold selection directly impacts both testing efficiency and quality assurance.

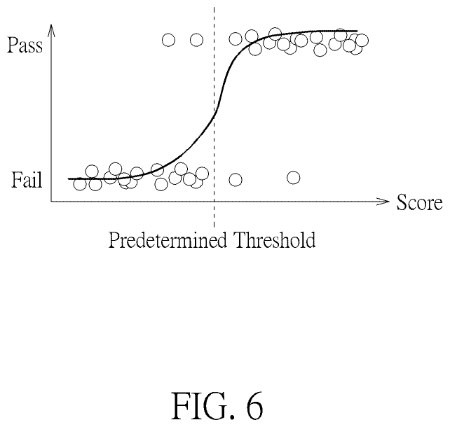

FIG. 6 illustrates how to determine predetermined thresholds for evaluating holistic qualification scores and item-specific qualification scores. Specifically, in the present invention, the predetermined thresholds are determined through statistical analysis of qualification scores from semiconductor devices that have passed basic testing. The qualification score distribution of these semiconductor devices typically exhibits a characteristic pattern as shown in the figure, which serves as the basis for threshold determination. In addition, the threshold determination also requires achieving an optimal balance between testing efficiency and quality assurance, as measured by defects part per million (DPPM). Setting more stringent thresholds necessitates more test items to be repeated under different environmental conditions, which reduces DPPM but decreases testing efficiency. Conversely, setting more lenient thresholds improves testing efficiency but leads to increased DPPM. Therefore, the predetermined thresholds are dynamically adjusted based on both the actual score distribution and target DPPM requirements to maintain optimal balance between efficiency and quality in the testing process.

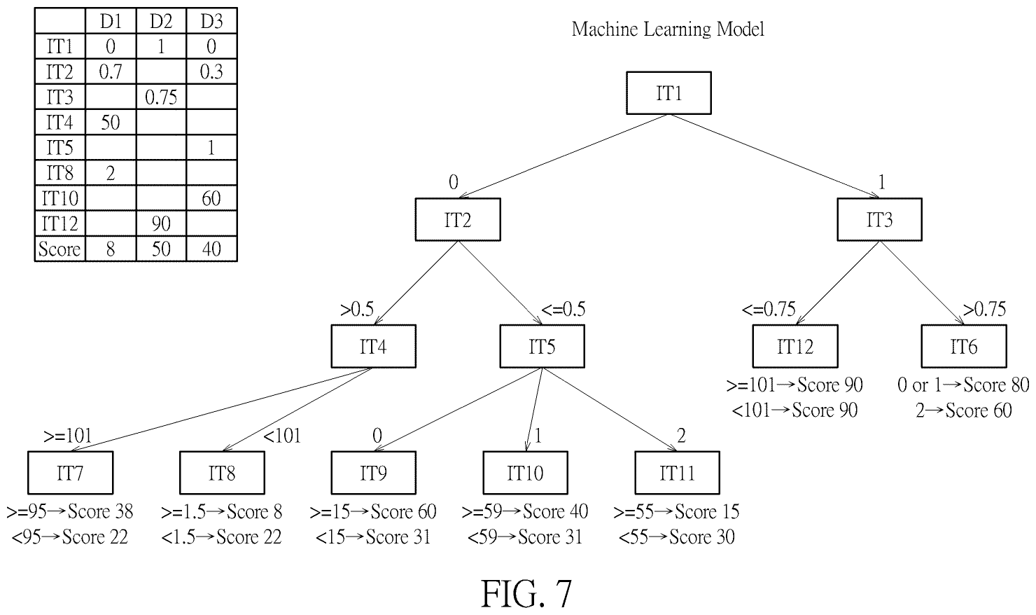

As discussed above, the testing control module 120 employs a machine learning model to generate qualification results for evaluating the necessity of repeating test items under different environmental conditions. FIG. 7 illustrates a partial structure of a machine learning model implemented in one embodiment of the present invention. It should be noted that the model structure shown in the figure represents only one possible implementation and does not limit the scope of the invention. Furthermore, the illustrated structure depicts only a portion of the complete model architecture.

As shown, the machine learning model adopted by the testing control module 120 comprises a decision tree structure configured to generate scores (which may be either holistic qualification scores or item-specific qualification scores as mentioned above). A training process for the decision tree of the machine learning model may include: collecting an initial dataset comprising comprehensive test results obtained from semiconductor devices tested under different environmental conditions (e.g., first environmental condition CP1 and second environmental condition CP2); performing data cleaning and filtering on the initial dataset to remove anomalous data points, thereby obtaining a refined training dataset; and finally, establishing the machine learning model based on this refined training dataset.

In practical application, the testing control module 120 inputs test results obtained under the first environmental condition CP1 into the machine learning model to generate predictions regarding test results under the second environmental condition CP2. For example, when a semiconductor device D1 obtains test results under the first environmental condition CP1 comprising a result of 0 for test item IT1 (which may be a categorical test item), 0.7 for test item IT2 (which may be a parametric test item), 50 for test item IT4 (which may be a parametric test item), and 2 for test item IT8 (which may be either a categorical test item or a parametric test item), the machine learning model illustrated in the figure is configured to generate an inference score of 8 for evaluating the necessity of the semiconductor device D1 to be further tested under the second environmental condition CP2.

In embodiments of the present invention, to enhance testing efficiency, the testing equipment 110 typically employs parallel testing, simultaneously performing one or more test items on multiple semiconductor devices during each touchdown operation. Consequently, when evaluating the necessity of repeating test items under different environmental conditions, the characteristics of this group-based testing approach must be considered.

The present invention implements the following strategy for group-based testing: when any semiconductor device within a group of semiconductor devices (or a plurality of semiconductor devices) requires repeated execution of specific test items under the second environmental condition, all semiconductor devices within the group of semiconductor devices (or a plurality of semiconductor devices) must undergo the same testing. Conversely, testing under the second environmental condition can be skipped for the entire group of semiconductor devices (or a plurality of semiconductor devices) only when all semiconductor devices within the group of semiconductor devices (or a plurality of semiconductor devices) meet the criteria for skipping testing. However, when only a single semiconductor device within the group of semiconductor devices (or a plurality of semiconductor devices) fails to meet the criteria for skipping testing, all semiconductor devices within the group of semiconductor devices (or a plurality of semiconductor devices) must undergo testing under the second environmental condition. This strategy maintains an optimal balance between testing efficiency and quality control while accommodating the practical constraints of parallel testing operations.

The present invention presents an innovative approach to semiconductor device testing optimization that enhances testing efficiency while maintaining quality assurance. The core innovation lies in intelligent prediction mechanism, which employs a machine learning model to evaluate the necessity of repeated testing under various environmental conditions. The present invention provides both holistic and granular optimization approaches. The holistic approach uses a holistic qualification score to determine whether all test items need to be repeated, while the granular approach uses item-specific qualification scores to enable selective execution of individual test items. In summary, the present invention effectively reduces testing redundancy while ensuring quality assurance across various operating conditions.

Embodiments in accordance with the present embodiments can be implemented as an apparatus, method, or computer program product. Accordingly, the present embodiments may take the form of an entirely hardware embodiment, an entirely software embodiment, or an embodiment combining software and hardware aspects that can all generally be referred to herein as a “module” or “system. ” Furthermore, the present embodiments may take the form of a computer program product embodied in any tangible medium of expression having computer-usable program code embodied in the medium. In terms of hardware, the present invention can be accomplished by applying any of the following technologies or related combinations: an individual operation logic with logic gates capable of performing logic functions according to data signals, and an application specific integrated circuit (ASIC), a programmable gate array (PGA) or a field programmable gate array (FPGA) with a suitable combinational logic.

The flowchart and block diagrams in the flow diagrams illustrate the architecture, functionality, and operation of possible implementations of systems, methods, and computer program products according to various embodiments of the present embodiments. In this regard, each block in the flowchart or block diagrams may represent a module, segment, or portion of code, which comprises one or more executable instructions for implementing the specified logical function(s). It is also noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions. These computer program instructions can be stored in a computer-readable medium that directs a computer or other programmable data processing apparatus to function in a particular manner, such that the instructions stored in the computer-readable medium produce an article of manufacture including instruction means which implement the function/act specified in the flowchart and/or block diagram block or blocks.

Those skilled in the art will readily observe that numerous modifications and alterations of the device and method may be made while retaining the teachings of the invention. Accordingly, the above disclosure should be construed as limited only by the metes and bounds of the appended claims

What is claimed is:

1. A testing method for use in semiconductor device testing, comprising:
performing at least one test item from a set of test items on at least one semiconductor device under a first environmental condition;
generating, via a machine learning model and based on a test result of the at least one test item, a qualification result that predicts at least one test result for one or more test items from the set of test items when performed on the at least one semiconductor device under a second environmental condition; and
determining, based on the qualification result, whether to perform the one or more test items from the set of test items on the at least one semiconductor device under the second environmental condition.

2. The testing method of claim 1, wherein the set of test items comprises at least one categorical test item and at least one parametric test item.

3. The testing method of claim 2, wherein each categorical test item is configured to generate a test result selected from a finite set of predefined outcomes, each predefined outcome indicating whether one or more specific parameters or functions of the at least one semiconductor device meet predetermined criteria through one or more iterations of testing.

4. The testing method of claim 3, further comprising:
discarding the at least one semiconductor device and skipping execution of the set of test items under the second environmental condition when a test result of a categorical test item indicates that the semiconductor device fails to meet the predetermined criteria through the one or more iterations of testing under the first environmental condition.

5. The testing method of claim 2, wherein each parametric test item is configured to generate a test result comprising a measurement value that quantifies a specific electrical, physical, or operational characteristic of the at least one semiconductor device.

6. The testing method of claim 1, wherein the qualification result comprises a holistic qualification score, and the step of determining whether to perform the one or more test items from the set of test items comprises:
skipping execution of the set of test items on the at least one semiconductor device under the second environmental condition when the holistic qualification score exceeds a predetermined threshold; and
performing the set of test items on the at least one semiconductor device under the second environmental condition when the holistic qualification score is lower than or equal to the predetermined threshold.

7. The testing method of claim 1, wherein the qualification result comprises at least one item-specific qualification score, and the step of determining whether to perform the one or more test items from the set of test items comprises:
skipping execution of a specific test item from the set of test items on the at least one semiconductor device under the second environmental condition when an item-specific qualification score that the specific test item corresponds to exceeds a predetermined threshold; and
performing the specific test item from the set of test items on the at least one semiconductor device under the second environmental condition when the item-specific qualification score that the specific test item corresponds to is lower than or equal to the predetermined threshold.

8. The testing method of claim 1, wherein the at least one semiconductor device comprises a plurality of semiconductor devices, and wherein the testing method further comprising:
performing the at least one test item from the set of test items on the plurality of semiconductor devices under a first environmental condition;
obtaining a plurality of test results of the at least one test item, wherein each test result corresponds to a respective semiconductor device from the plurality of semiconductor devices;
generating, via the machine learning model and based on the plurality of test results, a plurality of qualification results, wherein each qualification result is predictive of at least one test result for one or more test items from the set of test items when performed on the respective semiconductor devices under a second environmental condition; and
performing the one or more test items from the set of test items on the plurality of semiconductor devices under the second environmental condition if at least one qualification result indicates testing is required for its respective semiconductor device; and
skipping executing of the one or more test items from the set of test items on the plurality of semiconductor devices under the second environmental condition if all qualification results indicate testing is not required for their respective semiconductor devices.

9. A testing system for use in semiconductor device testing, comprising:
a testing equipment, configured to perform at least one test item from a set of test items on at least one semiconductor device under a first environmental condition; and
a testing control module configured to:
generate, via a machine learning model and based on a test result of the at least one test item, a qualification result that predicts of at least one test result for one or more test items from the set of test items when performed on the at least one semiconductor device under a second environmental condition;
determine, based on the qualification result, whether to control the testing equipment to perform the one or more test items from the set of test items on the at least one semiconductor device under the second environmental condition.

10. The testing system of claim 9, wherein the set of test items comprises at least one categorical test item and at least parametric test item.

11. The testing system of claim 10, wherein each categorical test item is configured to generate a test result selected from a finite set of predefined outcomes, each predefined outcome indicating whether one or more specific parameters or functions of the at least one semiconductor device meet predetermined criteria through one or more iterations of testing.

12. The testing system of claim 11, wherein the testing control module is configured to discard the at least one semiconductor device and control the testing equipment to skip execution of the set of test items on the at least one semiconductor device under the second environmental condition when a test result of a categorical test item indicates that the at least one semiconductor device fails to meet the predetermined criteria through the one or more iterations of testing under the first environmental condition.

13. The testing system of claim 10, wherein each parametric test item is configured to generate a test result comprising a measurement value that quantifies a specific electrical, physical, or operational characteristic of the at least one semiconductor device.

14. The testing system of claim 9, wherein the qualification result comprises a holistic qualification score, and the testing control module is configured to control the testing equipment to:
skip execution of the set of test items on the at least one semiconductor device under the second environmental condition when the holistic qualification score exceeds a predetermined threshold; and
perform the set of test items on the at least one semiconductor device under the second environmental condition when the holistic qualification score is lower than or equal to the predetermined threshold.

15. The testing system of claim 9, wherein the qualification result comprises at least one item-specific qualification score, and the testing control module is configured to control the testing equipment to:
skip execution of a specific test item from the set of test items on the at least one semiconductor device under the second environmental condition when an item-specific qualification score that the specific test item corresponds to exceeds a predetermined threshold; and
perform the specific test item from the set of test items on the at least one semiconductor device under the second environmental condition when the item-specific qualification score that the specific test item corresponds to is lower than or equal to the predetermined threshold.

16. The testing system of claim 9, wherein the at least one semiconductor device comprises a plurality of semiconductor devices, and wherein
the testing equipment is further configured to perform the at least one test item from the set of test items on the plurality of semiconductor devices under a first environmental condition and accordingly obtain a plurality of test results of the at least one test item, wherein each test result corresponds to a respective semiconductor device from the plurality of semiconductor devices;
the testing control module is further configured to generate, via the machine learning model and based on the plurality of test results, a plurality of qualification results, wherein each qualification result is predictive of at least one test result for one or more test items from the set of test items when performed on the respective semiconductor devices under a second environmental condition; and
the testing control module is further configured to control the testing equipment to:
perform the one or more test items from the set of test items on the plurality of semiconductor devices under the second environmental condition if at least one qualification result indicates testing is required for its respective semiconductor device; and
skip executing of the one or more test items from the set of test items on the plurality of semiconductor devices under the second environmental condition if all qualification results indicate testing is not required for their respective semiconductor devices.
